(19) United States
(12) Patent Application Publication
(10) Pub. No.: US 2016/0226367 A1
(43) Pub. Date: Aug. 4, 2016

(54) HIGH POWER ELECTRICAL MODULE AND HIGH POWER ELECTRICAL CIRCUIT

(71) Applicant: ALSTOM TECHNOLOGY LTD, Baden (CH)

(72) Inventors: Roman RAUBO, Downingtown, PA (US); Marek FURYK, Boyertown, PA (US); Kelvin CRAIK, Congleton Cheshire (UK)

(21) Appl. No.: 14/613,325

(22) Filed: Feb. 3, 2015

(51) Int. Cl. H02M 1/08; H02M 7/00; H05K 7/04; H05K 7/20; H05K 7/02

(52) U.S. Cl. CPC H02M 1/08; H05K 7/2039; H05K 7/023; H05K 7/04; H02M 7/003

(57) ABSTRACT

A high power electrical module comprising at least a first and a second electrical sub-module, at least a first bus bar that electrically connects together the first and the second electrical sub-module, and at least a first and a second heat sink on which are respectively mounted the first and the second electrical sub-module. The first and the second heat sink are arranged independently movable from each other in such manner to compensate the expansion of the first bus bar. The invention also relates on a voltage-source converter.

### TECHNICAL DOMAIN

The invention relates to the domain of high power electrical circuits, and more precisely to the high power electrical modules that are comprised in such high power electrical circuits.

### PREVIOUS ART

Some high power electrical circuits, like the one of a voltage-source converter, can comprise high power electrical modules such as full-bridge modules. Such modules are used, for example, for the connection of the remaining of the high power circuit with an electrical device such as a DC capacitor.

A high power electrical module, like the full-bridge module, comprises several high power electrical components, like Insulated Gate Bipolar Transistors, best known as IGBT, and diodes, several bus bars that are used to electrically connect the electrical components with each other, and heat sinks for cooling the electrical components, the electrical components being supported on the heat sinks.

More precisely, if we take the example of a typical full-bridge module, the electrical components are arranged in four electrical sub-modules that each one comprise three IGBTs and their corresponding antiparallel diodes. In each electrical sub-module, the three IGBTs are connected together in parallel to be equivalent to a single IGBT that can handle high current.

The electrical sub-modules are supported by pair on two respective heat sinks that are fixedly mounted in continuity. The IGBT high power terminals protrude from the electrical sub-modules all in the same direction in such way to define a connection plan. Four bus bars are used to connect the electrical sub-modules with each other and with the remaining of the high power circuit. They are planar metal sheets that are parallel to the connection plan. Each bus bars connects electrically and physically two modules with each other.

With such configuration, the bus bar and the parallel arrangement of the electrical sub-module allow the high power electrical module to handle high current. The evacuation of the heat generated by such high current in the electrical sub-modules is furnished by the heat sink.

However, if the heat sinks allow to evacuate a part of the heat generated by the flowing of current in the electrical sub-modules, the heat generated in the bus bars are sufficient to cause their expansion. Consequently, during the lifetime of the electrical module, the bus bars are constantly expanding and shrinking with the flowing and the stopping of the current in the electrical module. Such displacements are transmitted to the IGBT terminals that are connected to the bus bars and can, with time, damage them.

### PRESENTATION OF THE INVENTION

The invention is aimed to resolve these drawbacks.

In this purpose, the invention relates to a high power electrical module that comprises:
at least a first and a second electrical sub-module,
at least a first bus bar that electrically connects together the first and the second electrical sub-module,
at least a first and a second heat sink on which are respectively mounted the first and the second electrical sub-module,

the first and the second heat sink being arranged independently movable from each other in such manner to compensate expansion of the first bus bar.

With such mounting of the first and second heat sink, the movement of the first and second heat sink can compensate the expansion and the shrinking of the first bus bar. So the displacement caused by the expansion and the shrinking transmit to the terminals of the first and second electrical module are directly compensated by the displacement of the first and second heat sink relatively from each other. The terminals of the first and second electrical module are no more subject to bending that can damage them. Such high power module is more reliable than the one of previous art.

The high power electrical module could further comprise a support on which at least a part of the first and the second heat sink are mounted movable in translation.

Each heat sink from the first and the second heat sink could comprise at least a pin, the support comprises a groove to accommodate each heat sink pin arrange, thereby allowing a translation of at least a part of the corresponding heat sink.

The support could comprise for each heat sink from the first and the second heat sink, a receiving space to receive at least a part of said heat sink, the dimensions of the receiving spaces being adapted to allow a translation of the at least a part of the first and second heat sink sufficient to compensate the expansion of the first bus bar.

With such mountings of at least a part of the first and second heat sink ,the allowable movement of the first heat sink relatively to the second heat sink could be control so as to be sufficiently high to compensate the expansion of the first bus bar and sufficiently low to maintain the stiffness of the module.

The high power electrical module could further comprises:
a third and a fourth electrical module,
at least a second bus bar that electrically connects together the third and the fourth electrical sub-module.

The first heat sink could comprise a first and a second sub-heat sink, the first and third electrical sub-modules being respectively mounted on the first and second sub-heat sinks.

The second heat sink could comprise a third and a fourth sub-heat sink, the second and the fourth electrical sub-module being respectively mounted on the third and fourth sub-heat sinks.

The second and the fourth sub-heat sinks could be arranged independently movable from each other in such manner to compensate the expansion of the second bus bar.

The high power electrical module could further comprise:
a third and fourth bus bar that respectively connect together the first and the third electrical sub-module, and the second and fourth electrical sub-module.

The first and the second sub-heat sink could be arranged independently movable from each other in such manner to compensate the expansion of the third bus bar,

and the third and the fourth sub-heat sink could be arranged independently movable from each other in such manner to compensate the expansion of the fourth bus bar.

Such configurations of each heat sink into two sub-heat sink that support each one only one sub-module and that are independent from each other allow compensating movements relatively to each other so as to compensate the expansion of the fourth bus bar.

Each electrical sub-module could comprise at least an Insulated Gate Bipolar Transistor, called IGBT, and preferably three IGBT in parallel.

The high power electrical could form a full bridge module or a half bridge module adapted to connect an electrical device such as a DC capacitor to an electrical circuit.

Such modules beneficiate

The invention relates also on a voltage-source converter that comprises:
at least a full bridge module, and
a DC capacitor,
the full bridge module being a module of the invention.

Such voltage-source converter is more reliable than the one of the previous art as it full bridge module comprise terminals of a first and second electrical module that are no more subject to bending that can damage them.

### BRIEF DESCRIPTION OF THE DRAWINGS

The present invention will be better understood with the reading of the specification of a furnished embodiment which does not limit the scope of the invention. This specification refers to the annexed drawings in which:

FIG. 1 shown an electrical block diagram of a full bridge module according to the invention,

FIG. 2 shown an exploded view of a full bridge module according of the invention,

FIG. 3 shown a close-up in frontal view of the mounting of the sub-electrical module on the heat sinks shown in FIG. 2,

FIGS. 4a and 4b show a front view of respectively a bottom and a top sub-heat sink of a heat sink of the full bridge module shown on FIG. 2,

FIG. 5 shows a close-up of the mounting of the bottom sub-heat sinks on a support of the full bridge module shown on FIG. 2.

Same or similar parts in the different drawings use the same numerical reference to make easier the passage from one drawing to another.

### DETAILED PRESENTATION OF PARTICULAR EMBODIMENTS

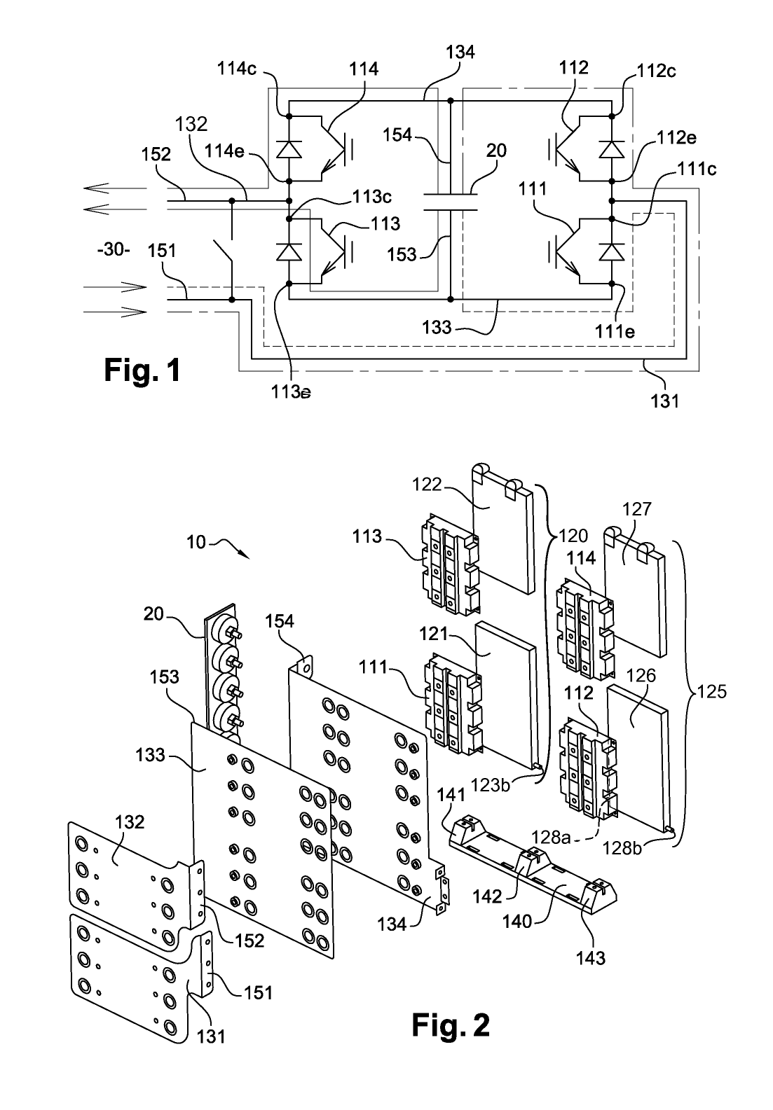

FIG. 1 and FIG. 2 illustrate respectively an electrical block diagram and an exploded view of an high power electrical module 10 used, for example, for the connection of the remaining of a high power electrical circuit, not illustrated, with an electrical device such as a DC capacitor 20, represented on FIG. 2 only by its terminals.

In FIGS. 1 and 2, the high power electrical module 10 is a full-bridge module. However, a high power electrical module of the invention could be of another type, such as a half-bridge module, without departing of the scope of the invention.

With this configuration of full bridge module, the high power electrical module 10 is disposed to make an interface between the DC capacitor 20 and the high power electrical circuit with the possibility to control the polarization of the connection between them.

The electrical module 10 comprises a first to a fourth electrical sub-module 111, 112, 113, 114, each one comprising three Insulated Gate Bipolar Transistors, best known as IGBTs, associated with three anti-parallel diodes. The IGBTs of an electrical sub-modules are connected in parallel in such manner that an electrical sub-module 111, 112, 113, 114, as illustrated on FIG. 1, are electrically equivalent to an single IGBT associated with a single anti-parallel diode.

So each electrical sub-module 111, 112, 113, 114 comprises six terminals, three for the IGBT collectors and three for the IGBT emitters. For simplification, in the following, the three IGBT collectors and the three IGBT emitters of a sub-module are respectively name the collector 111C, 112C, 113C, 114C and the emitter 111E, 112E, 113E, 114E of the electrical sub-module 111, 112, 113, 114.

The high power electrical module 10 further comprises:
a first bus bar 131 that is connected to the emitter 112E of the second electrical module 112 and to the collector 111C of the first electrical module 111, that comprises a first terminal 151 of the high power electrical module 10,
a second bus bar 132 that is connected to the emitter 114E of the fourth electrical module 114 and to the collector 113C of the third electrical module 113, and which comprises a second terminal 152 of the high power electrical module 10,
a third bus bar 133 that is connected to the emitter 113E of the third electrical module 113 and to the emitter 111E of the first electrical module 111, that comprises a third terminal 153 of the high power electrical module 10,
a fourth bus bar 134 that is connected to the collector 112C of the second electrical module 112 and to the collector 114C of the fourth IGBT 140, that comprises the fourth terminal 154 of the high power electrical module 10,
a first, a second heat sink 120, the first comprising a first and second sub-heat sink 121, 122 and the second heat sink 125 comprising a third and a fourth heat sink 126, 127, the first, the second, the third and the fourth electrical module 111, 112, 113, 114 being respectively supported on the first, the third, the second and the fourth sub-heat sink 121, 126, 122, 127,
a support 140 which support the first and the second heat sink 120, 125 by the means of respectively the first and the third sub-heat sink 121, 126.

The first and the second terminal 151, 152 are connected to the electrical circuit, whereas the third and the fourth terminal 153, 154 are connected to the DC capacitor 20 terminals.

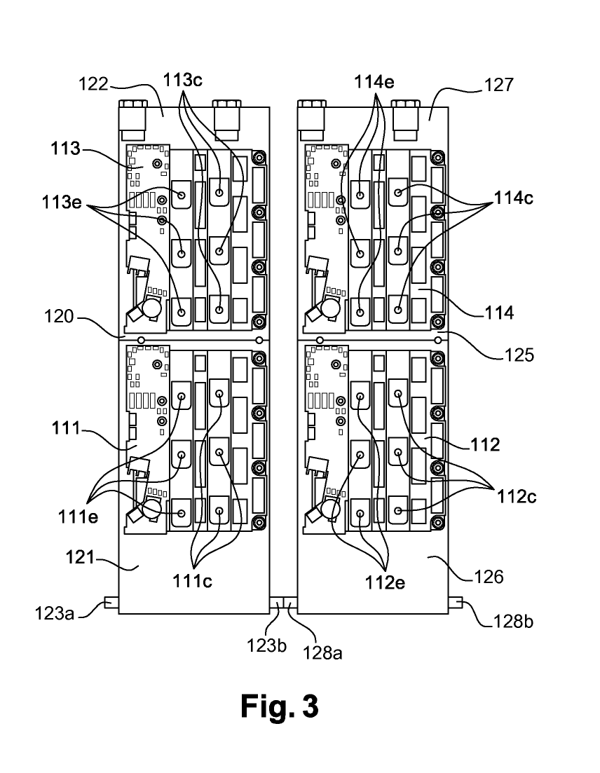

FIG. 3 shows the arrangement of the first, second, third and fourth sub heat sink 121, 122, 126, 127 which support respectively the first, third, second and fourth electrical sub-module 111, 113, 112, 114. The first, second, third and fourth sub-heat sink 121, 126, 122, 127 are planar shaped.

The first, second, third and fourth sub-heat sink 121, 122, 126, 127 are placed in continuity and defined a connection plan from which the collector and emitter of the electrical sub-module 111, 112, 113, 114 protrude.

As shown, the sub-heat sinks 121, 122, 126, 127 are placed independent from each other. In this way, the first, second, third and fourth sub-heat sink 121, 122, 126, 127 are only linked by the connection of the electrical sub-module 111, 112, 113, 114 given by the bus bars 131, 132, 133, 134.

With such configuration, the sub-heat sink 121, 122, 126, 127 are arranged to be movable relatively to each other in such manner to compensate the expansion of the bus bars 131, 132, 133, 134 when the current flows in it.

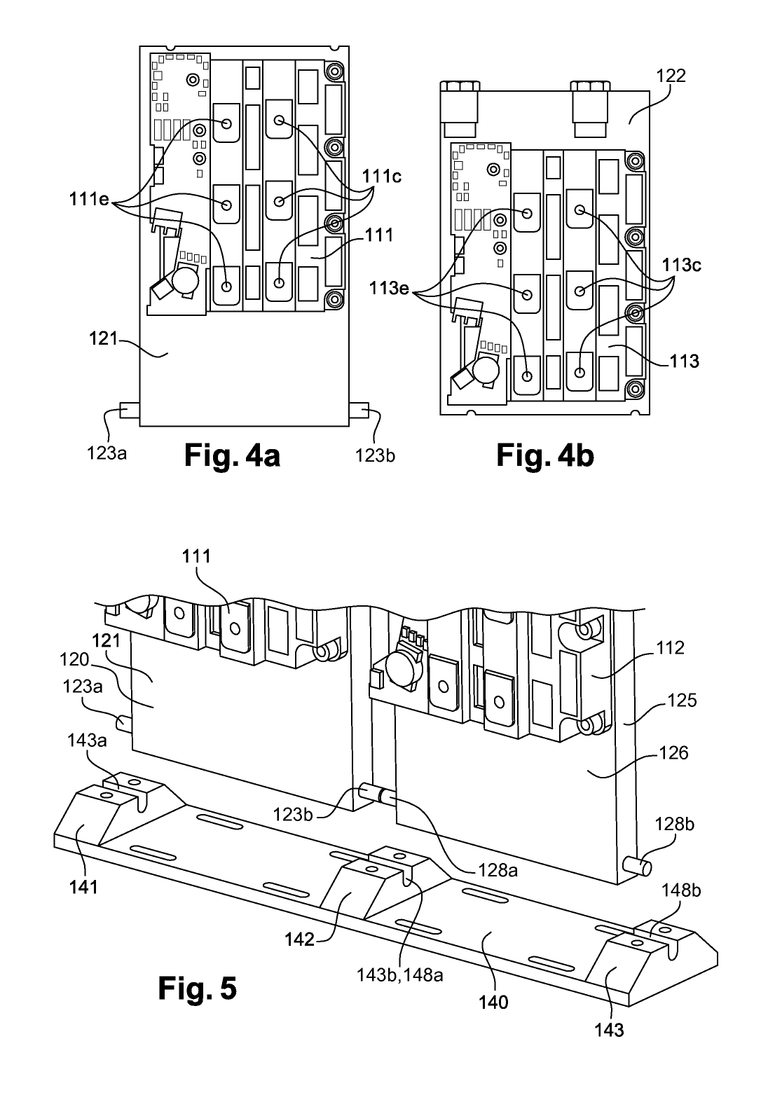

The sub-heat sinks 121, 122, 126, 127 can be, as illustrated on FIGS. 4a and 4b, of two different types, the upper and the bottom type. The first and the third sub-heat sink 121, 126 are from the bottom type whereas the second and the fourth sub-heat sink 122, 127 are from the upper type. The main difference between the sub-heat sink of the upper type and of the second type is that the sub-heat sinks of the bottom type have to be mounted on the support 140 and comprise to allow this mounting two pins 123a, 123b, 128a, 128b

As illustrated on FIGS. 5 and 4a, the first and third sub-heat sink 121, 126 each comprises two pins 123a, 123b, 128a, 128b at the bottom part of their edges. For each from the first and third sub-heat sink 123a, 123b, the two pins 123a, 123b, 128a, 128b extent along the same axis in opposite direction. This axis along which two pins of one of the first and third sub-heat sink 121, 126 extend is parallel to the connection plan.

The heat sink pins 123a, 123b, 128a, 128b are each accommodated in a corresponding groove 143a, 143b, 148a, 148b of the support 140.

The support 140 comprises a planar body from which three extensions protrude 141,142, 143. A first and a third extensions at the edge of the support 140 in which one of the groove 143a, 148b is furnished and a second extension 142 at central part of the support 140 in which two grooves 143b, 148a are furnished.

The space, call receiving space, between the first and the second extension 141, 142 and between the second and third extension 142, 143 are adapted to receive respectively a part of the first and a part of the second heat sink 120, 125 which are the first and the third sub-heat sink 121, 126 and is sufficient to allow the displacement of the first heat sink 121 relatively to the second heat sink 126 in order to compensate the expansion of the bus bar 131, 132, 133, 134. In other words, the receiving space between the first and the second extension 141, 142 and between the second and the third extension 142, 143 correspond to the lateral dimension of respectively the first and the third sub-heat sink 121, 126 at which it had been added a compensation gap. This compensation gap correspond at least to half the lateral maximal expansion of the bus bars 131, 132, 133, 134.

The grooves 143a, 143b, 148a, 148b, when the first and the second heat sink 120, 125 are mounted on the support, extended along the same axis than the heat sink pins 123a, 123b, 128a, 128b. The dimensions of the grooves 143a, 143b, 148a, 148b are complementary to the corresponding heat sink pins 123a, 123b, 128a, 128b while being sufficient to allow the translation of the heat sink pin 123a, 123b, 128a, 128b when the corresponding heat sink 120, 125 translates.

With such compensation gaps and the dimensions of the grooves 143a, 143b, 148a, 148b, a part of the first heat sink 120, the first sub-heat sink 121, and a part of the second heat sink 125, the third sub-heat sink 126 are mounted on the support 140 movable in translation in such manner to compensate the expansion of the bus bar 131, 132, 133, 134. So the first and the second heat sink 120, 125 are movable in translation in such manner to compensate the expansion of the bus bar 131, 132, 133, 134.

So, thanks to the mounting in translation of the first and third sub-heat sink 121, 126 on the support 140 and the independency of the second and fourth sub-heat sink 122, 127 regarding the first and the third sub-heat sink 121, 126, the sub-heat sinks 121, 126, 122, 127 can move relatively from each other in such way to compensate the expansion of the bus bars 131, 132, 133, 134 whereby the terminals of the electrical modules 111, 112, 113, 114 are not subject to bending.

In practical, such module could be used in a high power electrical circuit such as a voltage-source converter to connect a DC capacitor to the remaining of the voltage-source converter.

1. A high power electrical module comprising:
at least a first and a second electrical sub-module,
at least a first bus bar that electrically connects together the first and the second electrical sub-module,
at least a first and a second heat sink on which are respectively mounted the first and the second electrical sub-module,
the first and the second heat sinks are arranged independently movable from each other in such manner to compensate the expansion of the first bus bar.

2. The high power electrical module of claim 1, which further comprises a support on which at least a part of the first and the second heat sink are mounted movable in translation.

3. The high power electrical module of claim 2, wherein each heat sink from the first and the second heat sink comprises at least a pin, the support comprises a groove to accommodate each heat sink pin arrange, thereby allowing a translation of at least a part of the corresponding heat sink.

4. The high power electrical module of claim 2, wherein the support comprises for each heat sink from the first and the second heat sink, a receiving space to receive at least a part of said heat sink, the dimensions of the receiving spaces being adapted to allow a translation of the at least a part of the first and second heat sink sufficient to compensate the expansion of the first bus bar.

5. The high power electrical module claim 1 further comprising:
a third and a fourth electrical module,
at least a second bus bar that electrically connects together the third and the fourth electrical sub-module,
wherein the first heat sink comprises a first and a second sub-heat sink, the first and third electrical sub-modules being respectively mounted on the first and second sub-heat sinks,
wherein the second heat sink comprises a third and a fourth sub-heat sink, the second and the fourth electrical sub-module being respectively mounted on the third and fourth sub-heat sinks,
the second and the fourth sub-heat sinks being arranged independently movable from each other in such manner to compensate the expansion of the second bus bar.

6. The high power electrical module of claim 5, that further comprises:
a third and fourth bus bar that respectively connect together the first and the third electrical sub-module, and the second and fourth electrical sub-module,
wherein the first and the second sub-heat sink are arranged independently movable from each other in such manner to compensate the expansion of the third bus bar,
and wherein the third and the fourth sub-heat sink are arranged independently movable from each other in such manner to compensate the expansion of the fourth bus bar.

7. The high power electrical module according to claim 1, wherein each electrical sub-module comprises at least an Insulated Gate Bipolar Transistor, called IGBT, and preferably three IGBT in parallel.

8. The high power electrical module according to claim 1, which is adapted to form a full bridge module or a half bridge module adapted to connect an electrical device such as a DC capacitor to an electrical circuit.

9. A voltage-source converter that comprises:
at least a full bridge module, and
a DC capacitor,
at least a first and a second electrical sub-module,
at least a first bus bar that electrically connects together the first and the second electrical sub-module,
at least a first and a second heat sink on which are respectively mounted the first and the second electrical sub-module,
the first and the second heat sink are arranged independently movable from each other in such manner to compensate the expansion of the first bus bar.
